(19) United States
(12) Patent Application Publication
(10) Pub. No.: US 2002/0106903 A1
(43) Pub. Date: Aug. 8, 2002

(54) Manufacturing method of semiconductor device

(75) Inventors: Yoichiro Kurita, Tokyo (JP); Teruji Inomata, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/062,663

(22) Filed: Feb. 5, 2002

(30) Foreign Application Priority Data
Feb. 5, 2001 (JP) 2001-028147

(51) Int. Cl. H01L 21/44; H01L 21/302

(52) U.S. Cl. 438/707

(57) ABSTRACT

A manufacturing method of a semiconductor device in which wire connection means is connected to an electrode formed on a surface of an IC and made of Cu or a material mainly containing Cu, comprises an oxide film removal treatment step of applying a Cu oxide film removal treatment to the electrode, and a supersonic bonding step of bonding the wire connection means with supersonic to the electrode after the oxide film removal treatment step.

### BACKGROUND OF THE INVENTION

(i) Field of the Invention

The present invention relates to manufacturing methods of semiconductor devices, in particular, to manufacturing methods of semiconductor devices constructed in the manner that wire connection means is connected to each electrode formed on a surface of a semiconductor chip.

(ii) Description of the Related Art

Conventionally, as a method for manufacturing a semiconductor device such as an LSI (Large Scale Integrated-circuit) in which wires of a semiconductor chip are connected with wires of a package, for example known is a method for manufacturing a semiconductor device in the manner that a wire bonding process is performed to each electrode pad of the semiconductor chip. In this method, however, in case that the wires and electrode pads of the semiconductor chip are made of copper (Cu), as illustrated in FIG. 2, a bonding metallic layer 23 made of Au, Al, or the like, good in adaptability with each bonding wire 24, must be formed on a surface of each electrode pad 22 of the semiconductor chip 21. Such a construction requires a film formation apparatus or the like to form the bonding metallic layer 23 and so it may increase the manufacturing cost including a loss in yield due to the process.

On the other hand, another method is known in which wires of a semiconductor chip are connected with wires of a package without using bonding wires. In this method, inner leads of a TAB (Tape Automated Bonding) tape are directly bonded with supersonic to electrode pads of the semiconductor chip. Therefore, in case that the electrodes pads of the semiconductor chip and the inner leads of the TAB tape are made of Cu, good bonding of an inner lead of the TAB tape to the corresponding electrode pad of the semiconductor chip may become difficult owing to the presence of a Cu oxide film. This may cause a decrease in reliability of the semiconductor device.

As described above, in conventional methods for manufacturing a semiconductor device such as an LSI in which wires of a semiconductor chip are connected with wires of a package, in case that electrodes of the semiconductor chip and wire connection means to be connected to the electrodes are made of copper or a material mainly containing copper, there are fears of an increase in manufacturing cost, a decrease in reliability, etc.

### SUMMARY OF THE INVENTION

An object of the present invention is to provide a manufacturing method of a semiconductor device in which wire connection means can be connected to an electrode of a semiconductor chip, without bringing about an increase in manufacturing cost, a decrease in reliability, etc., in case that the electrode of the semiconductor chip and the wire connection means to be connected to the electrode are made of copper or a material mainly containing copper.

A manufacturing method of a semiconductor device according to the present invention in which wire connection means is connected to an electrode formed on a surface of an IC and made of Cu or a material mainly containing Cu, comprises an oxide film removal treatment step of applying a Cu oxide film removal treatment to the electrode, and a supersonic bonding step of bonding the wire connection means with supersonic to the electrode after the oxide film removal treatment step.

### BRIEF DESCRIPTION OF THE DRAWINGS

The above-mentioned and other objects, features, and advantages of this invention will become more apparent by reference to the following detailed description of the invention taken in conjunction with the accompanying drawings, wherein:

FIG. 1 illustrates a manufacturing method of a semiconductor device according to an embodiment of the present invention; and

FIG. 2 illustrates a conventional method for bonding a bonding wire to an electrode pad made of Cu.

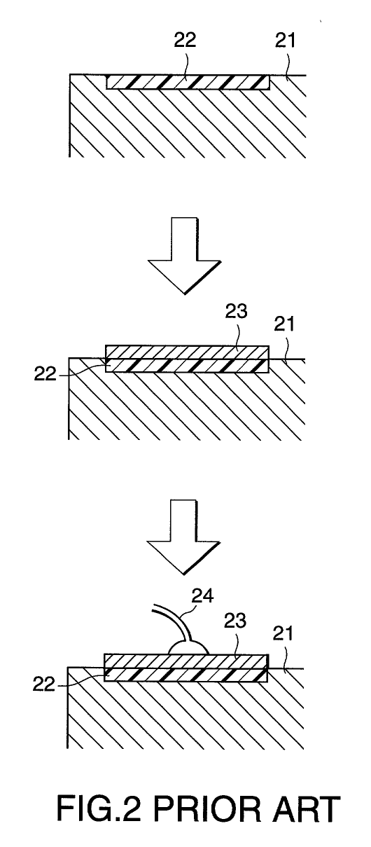

### DETAILED DESCRIPTION OF THE PREFERRED EMBODIMENT

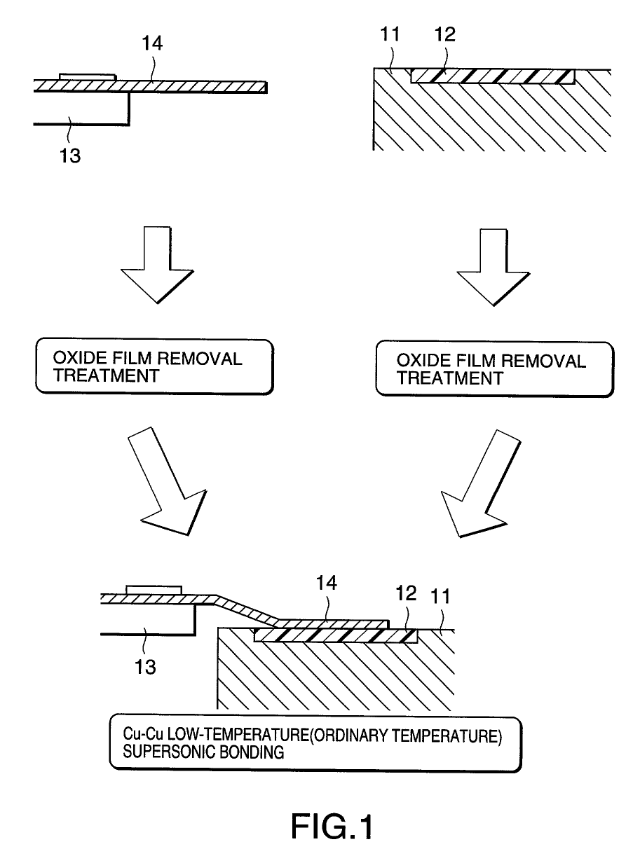

Hereinafter, an embodiment of the present invention will be described with reference to FIG. 1. FIG. 1 illustrates a manufacturing method of a semiconductor device according to the embodiment of the present invention. Referring to FIG. 1, a semiconductor chip 11 has an electrode pad 12 made of Cu. A TAB tape 13 has an inner lead 14 also made of Cu. For bonding the inner lead 14 of the TAB tape 13 to the electrode pad 12 of the semiconductor chip 11, initially, a Cu oxide film removal treatment is applied to the electrode pad 12 and the inner lead 14 so that a Cu oxide film may be removed from a surface of each of the electrode pad 12 and the inner lead 14 (oxide film removal treatment process). For removing the Cu oxide films, a usable method is of, e.g., etching the surfaces of the electrode pad 12 and the inner lead 14 (more specifically, a dry etching method with plasma, a wet etching method with oxalic acid, or the like).

After completion of the oxide film removal treatment, next, the inner lead 14 is bonded to the electrode pad 12 with supersonic at a low temperature (e.g., a temperature of 100° C. or less) at which Cu is hard to oxidize (supersonic bonding process). More specifically, in a state that one or more inner leads 14 of the TAB tape 13 are pressed onto the respective corresponding electrode pads 12 of the semiconductor chip 11, supersonic waves are applied to the inner leads 14 to bond the inner leads 14 to the electrode pads 12. After completion of the bonding process, a surface of the semiconductor chip 11 including the bonding portion between the electrode pad 12 and the inner lead 14 is sealed with a resin in order to protect the bonding portion from an external environment. Besides, after the oxide film removal treatment till the supersonic bonding process, the electrode pad 12 and the inner lead 14 are kept in an inert gas atmosphere such as nitrogen.

When the Cu oxide film removal treatment has been applied to the electrode pad 12 and the inner lead 14 upon supersonic bonding of the inner lead 14 to the electrode pad 12 as described above, the inner lead 14 can be bonded with supersonic to the electrode pad 12 in a state that no oxide film exists on the surface of either of the electrode pad 12 and the inner lead 14. Thus, in this embodiment, the bonding process of the inner lead 14 to the electrode pad 12 is not largely affected by the presence of an oxide film. Besides, formation of an oxidation-protective film or the like on the surface of the electrode pad 12 or inner lead 14 is unnecessary. Therefore, in case that the electrode pad 12 and the inner lead 14 are made of copper or a material mainly containing copper, the inner lead 14 can be connected to the electrode pad 12 without bringing about an increase in manufacturing cost, a decrease in reliability, etc.

Besides, since this embodiment uses a supersonic bonding process for bonding the inner lead 14 to the electrode pad 12, the inner lead 14 can be bonded to the electrode pad 12 with removing oxide films from the interface between the electrode pad 12 and the inner lead 14. Further, since the supersonic bonding process is performed at a low temperature at which Cu is hard to oxidize, this embodiment can avoid such bad influences as thermal expansion and deterioration of the TAB tape, which may arise in case of thermo-compression bonding. Therefore, the inner lead 14 can be well bonded to the electrode pad 12. Besides, since oxide films are removed by dry-etching or wet-etching the surfaces of the electrode pad 12 and the inner lead 14, the quantity of Cu oxide present in the interface between the electrode pad 12 and the inner lead 14, which may cause a decrease in reliability of bonding, can be extremely decreased.

Besides, in this embodiment, since the electrode pad 12 and the inner lead 14 are kept in an inert gas atmosphere such as nitrogen after the oxide film removal treatment till the supersonic bonding process, growth of any oxide film can be restrained and thereby the surfaces of the electrode pad 12 and the inner lead 14 can be kept in a state that the oxide films have been removed. Besides, since all electric circuits can be monometallic of Cu, high reliability and good electrical characteristics can be obtained. Further, since the inner lead 14 of the TAB tape 13 is used as wire connection means to be connected to the electrode pad 12 of the semiconductor chip 11 and this inner lead 14 is bonded with supersonic to the electrode pad 12 of the semiconductor chip 11 through a bump-less TAB process (TAB process in which no bump is formed on the semiconductor chip side), connection at a low cost and a high density can be realized.

Besides, in this embodiment, after the inner lead 14 is bonded with supersonic to the electrode pad 12, a surface of the semiconductor chip 11 including the bonding portion is sealed with a resin. Therefore, the bonding portion between the electrode pad 12 and the inner lead 14 can be protected from an external environment and corrosion of the bonding portion can be prevented. Further, since application of plating for preventing oxidation onto the surfaces of the electrode pad 12 and the inner lead 14, power supply wiring for plating is unnecessary. As a result, there is no influence of antenna effect due to the power supply wiring, improvements of electrical characteristics and an improvement of yield in wire patterning can be realized.

In this embodiment, a case wherein the inner lead 14 of the TAB tape 13 is connected to the electrode pad 12 of the semiconductor chip 11 is described. But, the present invention is not limited to this case. For example, the present invention is applicable also to a case wherein each terminal of a multilayer interconnection board made of a plastic, ceramic, or the like, is used as wire connection means and the terminal of the multilayer interconnection board is connected to an electrode of a semiconductor chip. Besides, each electrode of a semiconductor chip may not be in the form of an electrode pad. It may be in the form of e.g., an electrode bump protruding from the surface of the semiconductor chip. Further, in case of using a multilayer interconnection board as wire connection means, a method may be used in which supersonic waves are applied to the whole of a semiconductor chip to bond electrodes of the semiconductor chip to terminals of the multilayer interconnection board. Besides, in this embodiment, before the inner lead of the TAB tape is bonded with supersonic to the electrode pad of the semiconductor chip, oxide films that have been formed on the surfaces of the electrode pad and the inner lead are removed. However, such an oxide film removal treatment may be omitted if the electrode pad and the inner lead are kept in an inert gas atmosphere from the time immediately after they are made.

As described above, the present invention can provide a manufacturing method of a semiconductor device in which wire connection means can be connected to an electrode of a semiconductor chip, without bringing about an increase in manufacturing cost, a decrease in reliability, etc., in case that the electrode of the semiconductor chip and the wire connection means to be connected to the electrode are made of copper or a material mainly containing copper.

Although the invention has been described with reference to a specific embodiment, this description is not meant to be construed in a limiting sense. Various modifications of the disclosed embodiment will become apparent to persons skilled in the art upon reference to the description of the invention. It is therefore contemplated that the appended claims will cover any modifications or embodiments as fall within the true scope of the invention.

What is claimed is:

1. A manufacturing method of a semiconductor device in which wire connection means is connected to an electrode formed on a surface of an IC and made of Cu or a material mainly containing Cu, said method comprising:
an oxide film removal treatment step of applying a Cu oxide film removal treatment to said electrode; and
a supersonic bonding step of bonding said wire connection means with supersonic to said electrode after said oxide film removal treatment step.

2. The method according to claim 1, wherein an oxidation-protective film is formed on a surface of said electrode after said oxide film removal treatment step and said wire connection means is connected directly to said electrode through said oxidation-protective film in said supersonic bonding step.

3. The method according to claim 1, wherein a surface of said wire connection means is made of Cu or a material mainly containing Cu and said method further comprises a step of applying a Cu oxide film removal treatment to said wire connection means.

4. The method according to claim 3, wherein said electrode is in the form of an electrode pad.

5. The method according to claim 3, wherein said electrode is in the form of an electrode bump.

6. The method according to claim 3, wherein said wire connection means is an inner lead of a TAB tape.

7. The method according to claim 3, wherein said wire connection means is an electrode formed on an interconnection board.

8. The method according to claim 3, wherein said wire connection means is an electrode formed on an IC.

9. The method according to claim 3, wherein said supersonic bonding step comprises a step of bonding said wire connection means with supersonic to said electrode at a temperature of 100° C. or less.

10. The method according to claim 3, wherein said oxide film removal treatment step comprises, a step of removing said oxide film through an etching process.

11. The method according to claim 3, wherein said oxide film removal treatment step comprises a step of removing said oxide film through a dry etching process with plasma.

12. The method according to claim 3, wherein said oxide film removal treatment step comprises a step of removing said oxide film through a wet etching process.

13. The method according to claim 3, further comprising a step of keeping said IC in an inert gas atmosphere, between said oxide film removal treatment step and said supersonic bonding step.

14. The method according to claim 3, further comprising a step of keeping said wire connection means in an inert gas atmosphere, between said Cu oxide film removal treatment for said wire connection means and said supersonic bonding step.
